(19) United States
(12) Patent Application Publication
(10) Pub. No.: US 2016/0159953 A1
(43) Pub. Date: Jun. 9, 2016

(54) REAGENT FOR ENHANCING GENERATION OF CHEMICAL SPECIES

(71) Applicant: TOYO GOSEI CO., LTD., Ichikawa-shi, Chiba (JP)

(72) Inventors: Satoshi Enomoto, Kamagaya-shi (Chiba-ken) (JP); Takashi Miyazawa, Inzai-shi (Chiba-ken) (JP)

(21) Appl. No.: 14/392,350

(22) PCT Filed: Jun. 27, 2014
(86) PCT No.: PCT/JP2014/003450

§ 371 Date: Dec. 24, 2015

Related U.S. Application Data
(60) Provisional application No. 61/957,270, filed on Jun. 27, 2013.

(51) Int. Cl. C08F 220/28; G03F 7/039

(52) U.S. Cl. CPC C08F 220/28; G03F 7/039; C08F 2220/281

(57) ABSTRACT

A reagent that enhances acid generation of a photoacid generator and composition containing such reagent is disclosed.

### CROSS-REFERENCE TO RELATED APPLICATIONS

This application is a national phase entry under 35 U.S.C. §371 of International Patent Application PCT/JP2014/003450, filed Jun. 27, 2014, designating the United States of America and published in English as International Patent Publication WO 2014/208103 A 1 on Dec. 31, 2014, which claims the benefit under Article 8 of the Patent Cooperation Treaty and under 35 U.S.C. §119(e) to U.S. Provisional Patent Application Ser. No. 61/957,270, filed Jun. 27, 2013, the disclosure of which is hereby incorporated herein in its entirety by this reference.

### TECHNICAL FIELD

Several aspects of this disclosure relate to the fields of a reagent enhancing a generation of a chemical species such as an acid and base. An intermediate formed from the reagent functions as a photosensitizer, which also enhances the chemical species.

### BACKGROUND

Current high-resolution lithographic processes are based on chemically amplified resists (CARs) and are used to pattern features with dimensions less than 100 nm.

A method for forming pattern features with dimensions less than 100 nm is disclosed in U.S. Pat. No. 7,851,252 (filed on Feb. 17, 2009), the contents of the entirety of which are incorporated herein by this reference.

### BRIEF SUMMARY

A reagent that enhances generation of a chemical species, such as an acid, and a composition are disclosed in this disclosure. Typically, such reagent assists the generation of a Brönsted acid or base from a precursor. Furthermore, such reagent can apply to the generation of Lewis acid and base. Typically, such a reagent generates an intermediate such as a ketyl radical by having a hydrogen atom abstracted. Hence, in order to make a typical AGE achieve its function adequately in a composition such as a photoresist including the AGE, a photoacid generator, a resin containing a substituent that is to be decomposed by acid generated from the photoacid generator, it is preferred that the composition or the resin not include a compound or substituent of which a hydrogen atom is easily abstracted to avoid a competition between the abstraction reaction of hydrogen atom from AGE and that of the compound. A typical example of such compound or substituent is a phenol derivative or phenol group that is used for improving adhesiveness to an underlayer or substrate or as a proton source in photoresist compositions. Alternatively, a phenol derivative or phenol group having an electron accepting group such as a fluorine substituent and trifluoromethyl substituent is also preferable because a hydrogen atom of a hydroxyl group of such a derivative and group is not easily abstracted as a hydrogen atom. Coexistence of such a phenol derivative or phenol group and AGE in a composition or a polymer enables the composition and the polymer to contribute to the improvement of the adhesiveness to an underlayer or substrate and enhancement of acid generation at the same time even if a low-intensity light or particle ray such as extreme ultraviolet (EUV) light is used for irradiation of the composition or the polymer.

A composition relating to an aspect of this disclosure includes a reagent, a precursor, and a polymer. With regard to the composition, it is preferred that a generation of an intermediate from the reagent occurs, the intermediate enhances a chemical species from the precursor, and the composition does not contain a constituent inhibiting the generation of the intermediate from the reagent.

A composition relating to an aspect of the disclosure includes a reagent, a precursor, and a polymer. With regard to the composition, it is preferred that generation of an intermediate from the reagent occurs having a hydrogen atom of the reagent abstracted, the intermediate enhances a chemical species from the precursor, and the composition does not contain a constituent of which hydrogen atom is abstracted.

A composition relating to an aspect of this disclosure includes a reagent, a precursor, and a polymer. With regard to the composition, it is preferred that generation of an intermediate from the reagent occurs having a hydrogen atom of the reagent abstracted, the intermediate enhances a chemical species from the precursor, and the composition does not contain a constituent of which hydrogen atom is abstracted.

A composition relating to an aspect of the disclosure includes a reagent, a precursor, and a polymer. With regard to the composition, it is preferred that generation of an intermediate from the reagent occurs by having a hydrogen atom of the reagent abstracted, the intermediate enhances a chemical species from the precursor, and the polymer does not contain a substituent of which hydrogen atom is abstracted.

With regard to any one of the above compositions, it is preferred that the constituent contains an aromatic group and a hydroxyl group on the aromatic group.

With regard to any one of the above compositions, it is preferred that the substituent contains an aromatic group and a hydroxyl group on the aromatic group.

With regard to any one of the above compositions, it is preferred that the intermediate is a ketyl radical and the chemical species is an acid.

With regard to any one of the above compositions, it is preferred that the intermediate is a ketyl radical and the chemical species is an acid.

A composition relating to an aspect of this disclosure includes a reagent, a precursor, and a polymer. With regard to the composition, it is preferred that generation of an intermediate from the reagent occurs having a hydrogen atom of the reagent abstracted, the intermediate enhances a chemical species from the precursor, and the composition contains a constituent that contains an aromatic group, a hydroxy group on the aromatic group, and an electron-accepting group on the aromatic group.

With regard to the composition, it is preferred that the electron-accepting group is one of a halogen group, a nitro group, a cyano group, and alkyl group including at least one halogen atom.

A polymer relating to an aspect of the disclosure includes a reactive substituent that reacts with a chemical species.

With regard to the polymer, it is preferred that the polymer includes a function substituent that generates the chemical species or improves adhesiveness to a surface on which a composition including the polymer is placed.

With regard to the function substituent, it is preferred that the function substituent does not inhibit a generation of the chemical species.

With regard to the polymer, it is preferred that the polymer does not contain a substituent that inhibits a generation of the chemical species.

With regard to the polymer, it is preferred that the polymer further includes at least one of a precursor substituent that generates the chemical species and a reagent substituent that enhances a generation of the chemical species.

With regard to the polymer, it is preferred that the chemical species is acid, and the reagent substituent enhances a generation of the chemical species.

With regard to the polymer, it is preferred that the functional substituent has an aromatic group, a hydroxyl group, and at least one electro-accepting group.

With regard to the polymer, it is preferred that the functional substituent is a phenoxy group.

A method for manufacturing a device relating to an aspect of this disclosure includes applying a material including a photoresist including the composition of claim 1 to a substrate such that a coating film including the photoresist is formed on the substrate; a first exposure of the coating film to at least one of a first electromagnetic ray and a first particle ray such that a first portion of the coating film is exposed to the at least one of the first electromagnetic ray and the first particle ray while a second portion of the coating film is not exposed to the at least one of the first electromagnetic ray and the first particle ray; and a second exposure of the coating film with a second electromagnetic ray.

With regard to the method, it is preferred that the method further includes removing the first portion, and etching the substrate such that a third portion of the substrate on which the first portion has been present is etched.

With regard to the method, it is preferred that the first electromagnetic ray and the first particle ray are lights of which each wavelength is equal to or shorter than 200 nm or an electron beam, respectively.

With regard to the method, it is preferred that the first exposure of the coating film is carried out by a light of which wavelength is equal to or shorter than 15 nm.

With regard to the method, it is preferred that the second exposure of the coating film is carried out by a light of which wavelength is equal to or longer than 300 nm.

With regard to the method, it is preferred that the photoresist includes a reagent capable of generating an intermediate, and the intermediate enhances a chemical species from a precursor.

Ketyl radical has a reducing character and the intermediate enhances a generation of acid from the precursor. In other words, such reagent functions as an acid generation enhancer (AGE). The intermediate is converted to a product functioning as a photosensitizer. After formation of such product, an irradiation of the product results in its excited state, which can transfer energy or an electron to the precursor, or accept energy or electron from the precursor. Typically, the precursor generates the chemical species after receiving the energy or the electron or donating the electron. Since several AGEs are required for high electron donor character to enhance electron transfer to the precursor, such AGEs have at least one electron donating group on the aromatic ring such as an alkoxy group and a hydroxyl group. A reaction of the chemical species with a compound results in decomposition of the compound and regeneration of the chemical species. In other words, such reagent enhances generation of the chemical species in chemically amplified fashion, even if excitation means is altered in a set of processes.

A typical example for such AGE reagents is alcohol containing an aryl group. For example, a composition containing the reagent, a precursor that is to form a chemical species, and a compound that is to react with the chemical species can be applied as photoresist to manufacturing of electronic devices such as semiconductor devices and electro-optical devices. For example, after a coating film of the composition is exposed to an extreme ultraviolet (EUV) light or an electron beam (EB) in a first step, the coating film can be exposed to a light of which intensity is higher than that of the EUV light or the EB such as a UV light and a visible light. The composition can be applied to a chemically amplified reaction involved with a photoacid generator (PAG) and a resin containing a protective group such as an ester and ether group, which is to decompose by reacting with a chemical species such as acid generated from the PAG.

An oxidation reaction of aryl alcohol, which is a typical AGE, easily occurs to form a corresponding carbonyl compound. To attain the long-term stability of such AGE, the hydroxyl group of the AGE is preferably protected by a protective group such as a dialkoxy group, an alkoxycarbonyloxy group, an ether group, and a trisubstituted silyl group.

### BRIEF DESCRIPTION OF THE DRAWING

In the drawings, which illustrate what is currently considered to be the best mode for carrying out the disclosure:

FIG. 1 shows fabrication processes of a device, such as an integrated circuit (IC), using photoresist including an AGE.

### DETAILED DESCRIPTION

The disclosure is further described with the aid of the following illustrative Examples.

### Experimental Procedures

### Synthesis of 4-hydropyranylacetophenone

10.0 g of 4-hydroxyacetophenone and 9.89 g of 2H-dihydropyran are dissolved in 80.0 g of methylene chloride. 0.74 g of pyridinium p-toluenesulfonate is added to the methylene chloride solution containing 4-hydroxyacetophenone and 2H-dihydropyran. The mixture is stirred at 25 degrees Celsius for 3 hours. Thereafter, the mixture is further stirred after addition of 1% aqueous solution of sodium hydroxide. The organic phase is collected through separation by liquid extraction. 14.4 g of 4-hydropyranylacetophenone is obtained by evaporating solvents from the collected organic phase.

### Synthesis of 1-(4-tetrahydropyranylphenyl)ethanol (Example 1)

5.0 g of 4-hydropyranylacetophenone and 0.10 g of potassium hydroxide are dissolved in ethanol. 1.04 g of sodium boronhydride is added to the ethanol solution containing 4-hydropyranylacetophenone and potassium hydroxide. The mixture is stirred at 25 degrees Celsius for 3 hours. Thereafter, alkali in the mixture is neutralized by 10% aqueous solution of hydrochloric acid. The organic phase is collected through separation by liquid extraction using 100 g of methylene chloride. 4.52 g of 1-(4-tetrahydropyranylphenyl)ethanol is obtained by evaporating solvents from the organic phase.

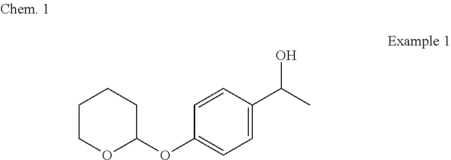 [SMILES: CC(O)c1ccc(OC2CCCCO2)cc1]

### Synthesis of Resin A

A solution containing 1.3 g of p-hydroxy-phenyl methacrylate, 4.4 g of alpha-methacryloyloxy-gamma-butylolactone, 4.4 g of 2-methyladamantane-2-methacrylate, and 5.2 g of 3-hydroxyadamantane-1-methacrylate, 0.33 g of butyl mercaptane, 0.85 g of dimethyl-2,2′-azobis(2-methylpropionate) and 26.1 g of tetrahydrofuran is prepared. Butyl mercaptane is converted into a corresponding radical that adjusts the polymer chain length.

The prepared solution is added dropwise for 4 hours to 20.0 g of tetrahydrofuran placed in a flask with stirring and boiling. After the addition of the prepared solution, the mixture is heated to reflux for 2 hours and cooled to room temperature. Addition of the mixture dropwise to a mixed liquid containing 160 g of hexane and 18 g of tetrahydrofuran (with vigorous stirring) precipitates the copolymer. The copolymer is isolated by filtration. Purification of the copolymer is carried out by vacuum drying following two washings with 70 g of hexane. Thereby, 8.0 g of white powder of the copolymer (Resin A) is obtained.

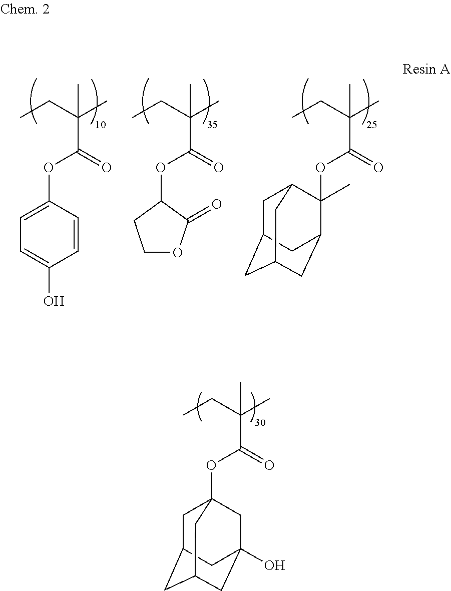

### Synthesis of Resin B

A solution containing 1.6 g of p-acetoxyphenyl methacrylate, 4.4 g of alpha-methacryloyloxy-gamma-butylolactone, 4.4 g of 2-methyladamantane-2-methacrylate, 5.2 g of 3-hydroxyadamantane-1-methacrylate, 0.33 g of butyl mercaptane, 0.85 g of dimethyl-2,2′-azobis(2-methylpropionate) and 26.1 g of tetrahydrofuran is prepared. The prepared solution is added dropwise for 4 hours to 20.0 g of tetrahydrofuran placed in a flask with stirring and boiling. After the addition of the prepared solution, the mixture is heated to reflux for 2 hours and cooled to room temperature. Addition of the mixture dropwise to a mixed liquid containing 160 g of hexane and 18 g of tetrahydrofuran (with vigorous stirring) precipitates the copolymer. The copolymer is isolated by filtration. Purification of the copolymer is carried out by vacuum drying following two washings with 70 g of hexane. Thereby, 8.2 g of white powder of the copolymer is obtained.

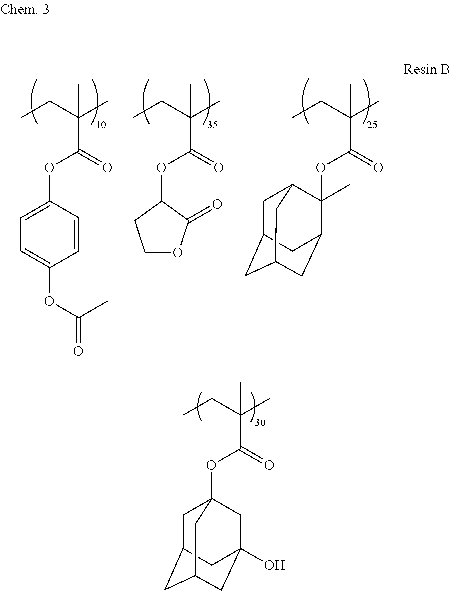

### Synthesis of Resin C

A solution containing 1.4 g of 2,3,5,6-tetrafluoro-4-hydroxystyrene, 4.4 g of alpha-methacryloyloxy-gamma-butylolactone, 4.4 g of 2-methyladamantane-2-methacrylate, 5.2 g of 3-hydroxyadamantane-1-methacrylate, 0.33 g of butyl mercaptane, 0.85 g of dimethyl-2,2′-azobis(2-methylpropionate) and 26.1 g of tetrahydrofuran is prepared. The prepared solution is added dropwise for 4 hours to 20.0 g of tetrahydrofuran placed in a flask with stirring and boiling. After the addition of the prepared solution, the mixture is heated to reflux for 2 hours and cooled to room temperature. Addition of the mixture dropwise to a mixed liquid containing 160 g of hexane and 18 g of tetrahydrofuran (with vigorous stirring) precipitates the copolymer. The copolymer is isolated by filtration. Purification of the copolymer is carried out by vacuum drying following two washings with 70 g of hexane. Thereby, 7.9 g of white powder of the copolymer is obtained.

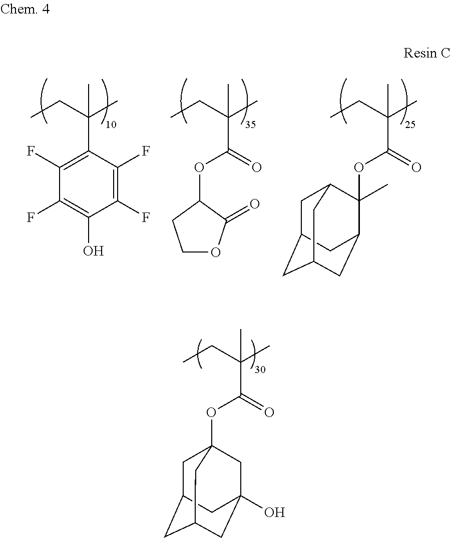

### Synthesis of Resin D

A solution containing 1.9 g of 2,6-bis(trifluoromethyl)-4-hydroxystyrene, 4.4 g of alpha-methacryloyloxy-gamma-butylolactone, 4.4 g of 2-methyladamantane-2-methacrylate, 5.2 g of 3-hydroxyadamantane-1-methacrylate, 0.33 g of butyl mercaptane, 0.85 g of dimethyl-2,2′-azobis(2-methylpropionate) and 26.1 g of tetrahydrofuran is prepared. The prepared solution is added for 4 hours to 20.0 g of tetrahydrofuran placed in a flask with stirring and boiling. After the addition of the prepared solution, the mixture is heated to reflux for 2 hours and cooled to room temperature. Addition of the mixture dropwise to a mixed liquid containing 160 g of hexane and 18 g of tetrahydrofuran (with vigorous stirring) precipitates the copolymer. The copolymer is isolated by filtration. Purification of the copolymer is carried out by vacuum drying following two washings with 70 g of hexane. Thereby, 8.2 g of white powder of the copolymer is obtained.

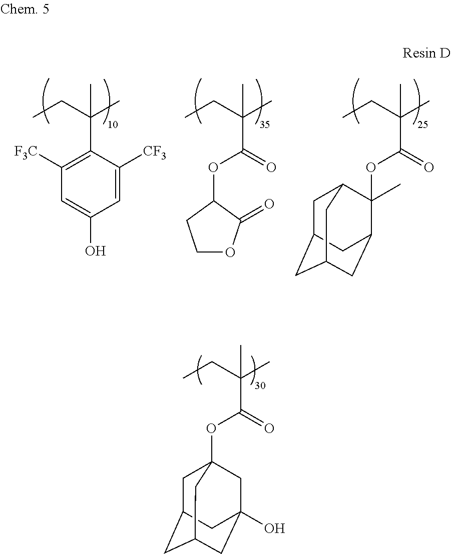

### Preparation of Samples for Evaluation (Evaluation Samples)

Evaluation Sample 1 is prepared by dissolving 300 mg of Resin A, 24.9 mg of diphenyliodonium nonafluorobutanesulfonate (DPI-PFBS) as a photoacid generator, and 15.0 mg of coumarin 6 as an indicator in 2000 mg of cyclohexanone.

Evaluation Samples 2 to 5 are prepared by dissolving 6.0 mg of 1-(4-tetrahydropyranylphenyl)ethanol, 300 mg of one of Resins A-D, 24.9 mg of DPI-PFBS as a photoacid generator, and 15.0 mg of coumarin 6 as an indicator in 2000 mg of cyclohexanone. Sample components are as follows:

Evaluation Sample 2: Resin A, DPI-PFBS, Example 1, and cyclohexanone;

Evaluation Sample 3: Resin B, DPI-PFBS, Example 1, and cyclohexanone;

Evaluation Sample 4: Resin C, DPI-PFBS, Example 1, and cyclohexanone; and

Evaluation Sample 5: Resin D, DPI-PFBS, Example 1, and cyclohexanone.

Evaluation of Efficiency of Acid Generation

Each of coating films of the Evaluation Samples is formed on a 4-inch quartz wafer by spin-coating of Evaluation Samples 1 to 5. Each of the coating films is irradiated with electron beams of which volumes are 0, 10, 20, 30, and 40 microC/cm² output by an electron beam lithography apparatus. Subsequent to the electron-beam exposures, the efficiencies for the films are obtained by plotting absorbances at 534 nm where absorption band of protonated coumarin 6 generated by the respective volumes of electron beams is observed.

Table 1 shows the relative acid-generation efficiencies for the Evaluation Samples 1 to 5. In Table 1, the acid-generation efficiency for Evaluation Sample 1 is used as a benchmark. The results of Evaluation Samples 1 and 2 shown in Table 1 indicate that the acid-generation efficiency is not improved even by the addition of 1-(4-tetrahydropyranylphenyl)ethanol because phenoxy radical is more stable than ketyl radical. Therefore, ketyl radical is not generated from 1-(4-tetrahydropyranylphenyl)ethanol in phenoxy-containing resin. Thereby, 1-(4-tetrahydropyranylphenyl)ethanol addition effect is not clearly observed.

On the other hand, the results of Evaluation Samples 3 to 5 in Table 1 indicate that the acid-generation efficiency is improved by the reduction of the photoacid generator by ketyl radical formed from 1-(4-tetrahydropyranylphenyl)ethanol. As the result, protection of phenoxy group or electron-withdrawing groups attachment to phenyl structure have the effect of preventing hydrogen abstraction from phenoxy group. Thereby, 1-(4-tetrahydropyranylphenyl)ethanol functions as an Acid Generation Enhancer (AGE).

TABLE 1
Relative acid-generation efficiency for Samples 1 to 5

| | Relative acid-generation |
|---|---|
| | efficiency |
| Sample 1 | 1.00 |
| Sample 2 | 1.00 |
| Sample 3 | 1.20 |
| Sample 4 | 1.27 |
| Sample 5 | 1.33 |

Based upon the results, a reactive intermediate having reducing character is considered to enhance the efficiency of acid generation.

Examples 2, 3, 4, and 5 are also used as AGEs.

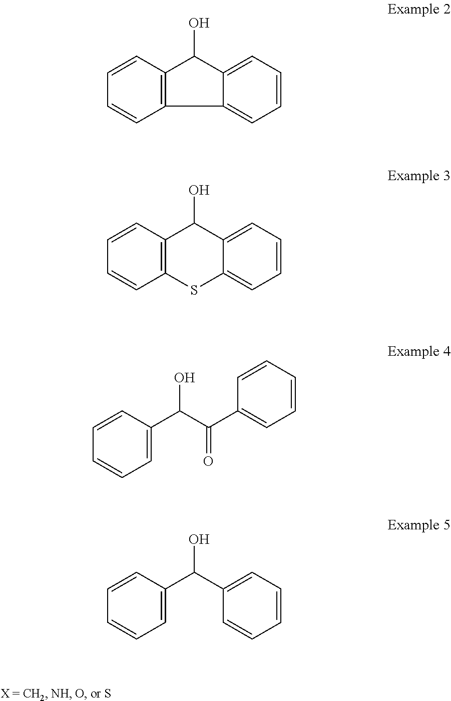 [SMILES: OC1c2ccccc2-c2ccccc21 ; OC1c2ccccc2Sc2ccccc21 ; O=C(c1ccccc1)C(O)c1ccccc1 ; OC(c1ccccc1)c1ccccc1]

Ketyl radicals generated from Examples 2-5 by having a hydrogen atoms of hydroxyl groups abstracted are reducing characters and oxidized to form corresponding ketones that exhibit wavelength longer than the corresponding alcohols. Therefore, utilization of Examples 2-5 as AGEs enable the performance of multi-step lithographic exposure that can be used for a variety of devices such as semiconductor devices and electro-optical devices. Typically, after an EUV light or electron beam is used for a first lithographic exposure, a light of which wavelength is longer than the EUV light is used for a second lithographic exposure.

A photoresist including any one of Evaluation Samples 3-5 can be applied to fabrication processes of a device such as integrated circuit (IC).

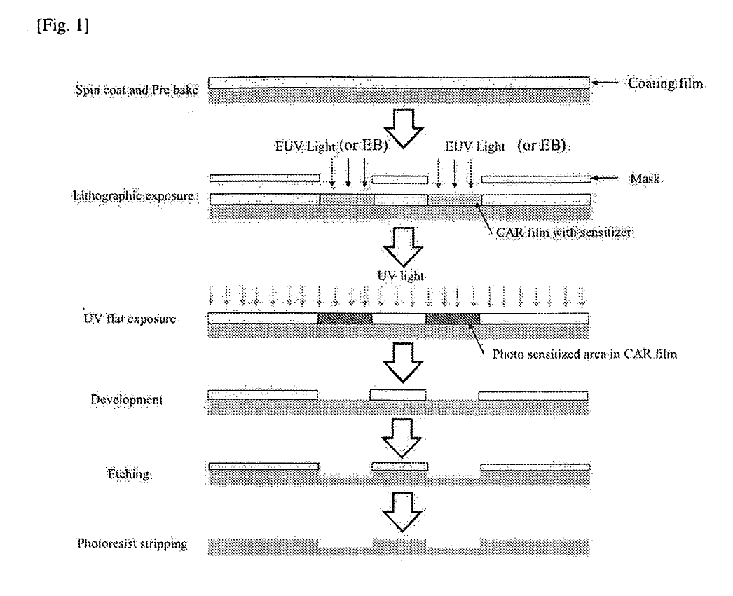

FIG. 1 shows fabrication processes of a device such as integrated circuit (IC) using the photoresist.

A silicon wafer is provided. The surface of a silicon wafer is oxidized by heating the silicon wafer in the presence of oxygen gas.

The photoresist is applied to the surface of an Si wafer by spin coating to form a coating film. The coating film is prebaked.

An irradiation of the coating film with an EUV light through a mask is carried out after prebake of the Si wafer. The deprotection reaction of the coating film is induced by acid generated by photoreaction of the photoacid generator and assistance by the AGE.

An electron beam can be used instead of the EUV light.

After the EUV irradiation of the coating film, an irradiation of the coating film with a light of which wavelength is equal to or longer than 300 nm is carried out without any mask.

Development of the coating film that has been irradiated with the EUV light and the light of which wavelength is equal to or longer than 300 nm is performed after the prebake.

The coating film and the silicon wafer are exposed to plasma. After that, the remaining film is removed.

An electronic device such as integrated circuit is fabricated utilizing the processes shown in FIG. 1. The deterioration of the device due to the irradiation with a light is suppressed compared to existing photoresists since times for irradiation of the coating film is shortened.

1.-7. (canceled)

8. A polymer, comprising:
first substituent that contains at least one aromatic group, a hydroxy group on the aromatic group, and an electron accepting group on the aromatic group; and
a second substituent that contains a reactive substituent reacting with a chemical species.

9. The polymer of claim 8, wherein the electron accepting group is one of halogen group, alkyl group including at least one halogen atom, nitro group, cyano group, and nitro group.

10. (canceled)

11. The polymer according to claim 8, further comprising:
a function substituent that generates the chemical species or improves adhesiveness to a surface on which a composition including the polymer is placed,
wherein the function substituent does not inhibit a generation of the chemical species.

12. The polymer according to claim 8, wherein the polymer does not contain a substituent that inhibits a generation of the chemical species.

13. The polymer according to claim 8, further comprising:
at least one of a precursor substituent that generates the chemical species and a reagent substituent that enhances a generation of the chemical species.

14. The polymer according to claim 13, wherein:
the chemical species is acid; and
the reagent substituent enhances a generation of the chemical species.

15.-21. (canceled)

22. The polymer of claim 8, wherein the reactive substituent comprises a protective group.

23. The polymer of claim 22, wherein the protective group is an ester group or an ether group.

24. A composition comprising:
the polymer of claim 8.

25. A polymer comprising:
a first substituent comprising:
at least one aromatic group,
a hydroxy group on the aromatic group, and
an electron accepting group selected from the group consisting of halogen group, alkyl group including at least one halogen atom, nitro group, cyano group, and nitro group on the aromatic group; and
a second substituent comprising a reactive substituent reacting with a chemical species.

26. The polymer of claim 25, further comprising:
a substituent that generates the chemical species.

27. The polymer of claim 25, wherein the polymer does not comprise a substituent that inhibits generation of the chemical species.

28. The polymer of claim 25, further comprising:
a reagent substituent that enhances generation of the chemical species.

29. The polymer of claim 28, wherein the chemical species is acid.

30. The polymer of claim 25, wherein the reactive substituent comprises a protective group.

31. The polymer of claim 30, wherein the protective group is an ester group or an ether group.
